(19) United States
(12) Patent Application Publication
(10) Pub. No.: US 2025/0105088 A1
(43) Pub. Date: Mar. 27, 2025

(54) SEMICONDUCTOR PACKAGE

(71) Applicant: SAMSUNG ELECTRONICS CO., LTD., Suwon-si (KR)

(72) Inventors: Hwanjoo Park, Suwon-si (KR); Jaesun Kim, Suwon-si (KR)

(21) Appl. No.: 18/891,644

(22) Filed: Sep. 20, 2024

(30) Foreign Application Priority Data
Sep. 27, 2023 (KR) 10-2023-0131165

(51) Int. Cl. H01L 23/367; H01L 23/00; H01L 23/373; H01L 23/48; H01L 25/065; H05K 1/18

(52) U.S. Cl. CPC H01L 23/3677; H01L 23/3736; H01L 23/481; H01L 24/16; H01L 24/14; H01L 24/32; H01L 24/73; H01L 25/0655; H01L 2224/1403; H01L 2224/16225; H01L 2224/32225; H01L 2224/73204; H01L 2924/1815; H05K 1/181

(57) ABSTRACT

An example semiconductor package includes a first redistribution structure, a first chip on the first redistribution structure, a molding member on the first redistribution structure to surround the first chip, a conductive pillar penetrating the molding member in a vertical direction, a second redistribution structure on the first chip and the molding member, a second chip on the second redistribution structure, and a third chip on the second redistribution structure and separated from the second chip in a horizontal direction. The first redistribution structure includes a first redistribution insulating layer and a first redistribution pattern. The second redistribution structure includes a second redistribution insulating layer and a second redistribution pattern. The first chip includes a first semiconductor substrate and a through electrode penetrating the first semiconductor substrate in the vertical direction. The through electrode is in contact with the second redistribution pattern.

### CROSS-REFERENCE TO RELATED APPLICATION

This application claims priority under 35 U.S.C. § 119 to Korean Patent Application No. 10-2023-0131165, filed on Sep. 27, 2023, in the Korean Intellectual Property Office, the disclosure of which is incorporated by reference herein in its entirety.

### BACKGROUND

Recently, demand for portable devices in the electronic product market has rapidly increased, and according to this, electronic components mounted in these electronic products have been continuously demanded to be small and light. To make electronic components small and light, semiconductor packages mounted in the electronic components have been demanded to process high-capacity data with a small volume. Along with the miniaturization and lightening of semiconductor packages, research for thin semiconductor packages configured to easily discharge heat generated therein has been conducted.

### SUMMARY

The present disclosure relates to semiconductor packages, including a semiconductor package with a reduced thickness and an improved thermal characteristic.

In addition, the problem to be addressed by the technical idea of the present disclosure is not limited to the problem mentioned above, and the other problems could be clearly understood by those of ordinary skill in the art from the description below.

The present disclosure provides semiconductor packages below to address the technical problems.

In some implementations, a semiconductor package includes a first redistribution structure including a first redistribution insulating layer and a first redistribution pattern formed in the first redistribution insulating layer, a first chip on the first redistribution structure, a molding member on the first redistribution structure so as to surround the first chip, a conductive pillar penetrating the molding member in a vertical direction, a second redistribution structure on the first chip and the molding member and including a second redistribution insulating layer and a second redistribution pattern formed in the second redistribution insulating layer, a second chip on the second redistribution structure, and a third chip on the second redistribution structure and spaced apart from the second chip in a horizontal direction, wherein the first chip further includes a first semiconductor substrate and a through electrode penetrating the first semiconductor substrate in the vertical direction, and the through electrode is in physical contact with the second redistribution pattern.

In some implementations, a semiconductor package includes a first redistribution structure including a first redistribution insulating layer and a first redistribution pattern formed in the first redistribution insulating layer, a first chip on the first redistribution structure, a molding member on the first redistribution structure so as to surround the first chip, a conductive pillar penetrating the molding member in a vertical direction, a second redistribution structure on the first chip and the molding member and including a second redistribution insulating layer and a second redistribution pattern formed in the second redistribution insulating layer, a second chip on the second redistribution structure, a third chip on the second redistribution structure and spaced apart from the second chip in a horizontal direction, and a heat-dissipating member on the second chip, wherein the first chip further includes a first semiconductor substrate and a through electrode penetrating the first semiconductor substrate in the vertical direction, the through electrode is in physical contact with the second redistribution pattern, an upper surface of the second chip is at a lower level than an upper surface of the third chip, and a circuit gap of the second chip is narrower than a circuit gap of the first chip.

In some implementations, a semiconductor package includes a first redistribution structure including a first redistribution insulating layer and a first redistribution pattern formed in the first redistribution insulating layer, a first passive device beneath the first redistribution structure, a first chip on the first redistribution structure, a molding member on the first redistribution structure so as to surround the first chip, a conductive pillar penetrating the molding member in a vertical direction, a second redistribution structure on the first chip and the molding member and including a second redistribution insulating layer and a second redistribution pattern formed in the second redistribution insulating layer, a second chip on the second redistribution structure, a plurality of second passive devices on the second redistribution structure so as to surround side surfaces of the second chip, a third chip on the second redistribution structure and spaced apart from the second chip in a horizontal direction, a metal layer formed on an upper surface of the second chip, and a heat-dissipating member coupled to the upper surface of the metal layer, wherein the first chip further includes a first semiconductor substrate and a through electrode penetrating the first semiconductor substrate in the vertical direction, the through electrode is in physical contact with the second redistribution pattern, the upper surface of the second chip is at a lower level than an upper surface of the third chip, a circuit gap of the second chip is narrower than a circuit gap of the first chip, and each of the metal layer and the heat-dissipating member includes copper.

### BRIEF DESCRIPTION OF THE DRAWINGS

Implementations of the present disclosure will be more clearly understood from the following detailed description taken in conjunction with the accompanying drawings.

FIGS. 1A and 1B are cross-sectional views illustrating example semiconductor packages.

FIG. 2 is a cross-sectional view illustrating an example of a semiconductor package.

FIG. 3 is a cross-sectional view illustrating another example of a semiconductor package.

FIG. 4 is a cross-sectional view illustrating another example of a semiconductor package.

FIG. 5A is a cross-sectional view illustrating another example of a semiconductor package.

FIG. 5B is a top view illustrating an example of a semiconductor package.

### DETAILED DESCRIPTION

Hereinafter, implementations are described in detail with reference to the accompanying drawings. Like reference numerals in the drawings denote like elements, and thus their repetitive description will be omitted.

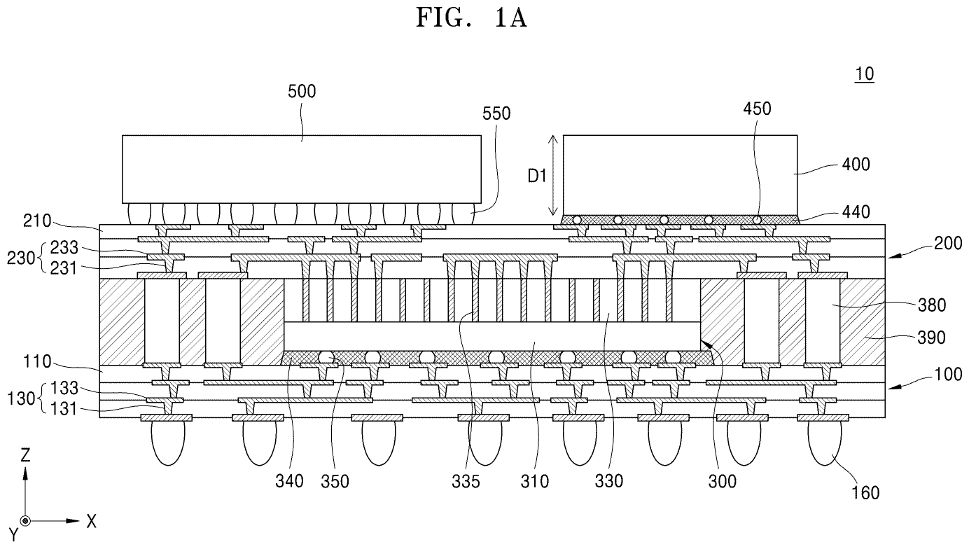

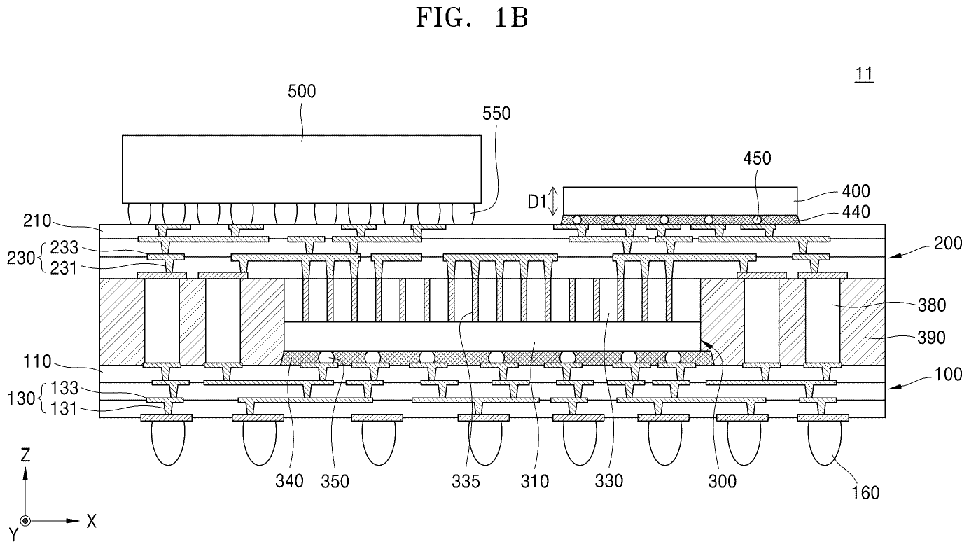

FIGS. 1A and 1B are cross-sectional views illustrating example semiconductor packages 10 and 11.

Referring to FIGS. 1A and 1B, the semiconductor packages 10 and 11 may include a first redistribution structure 100, a first chip 300, a molding member 390, a conductive pillar 380, a second redistribution structure 200, a second chip 400, and a third chip 500.

The first redistribution structure 100 may include upper and lower surfaces that are opposite to each other, and at least one of the upper and lower surfaces of the first redistribution structure 100 may be flat. The first redistribution structure 100 may be beneath the first chip 300 and may electrically connect between the first chip 300 and an external connection terminal 160 and between the conductive pillar 380 and the external connection terminal 160. The first redistribution structure 100 may include a first redistribution insulating layer 110 and a first redistribution pattern 130.

The first redistribution insulating layer 110 may be provided as a plurality of insulating layers stacked in one direction, and the first redistribution pattern 130 may be formed in the plurality of insulating layers that are stacked.

In the drawings below, it may be understood that the direction in which the plurality of insulating layers of the first redistribution insulating layer 110 are stacked is a Z-axis direction and an X-axis direction and a Y-axis direction are perpendicular to each other on a plane having the Z-axis direction as a normal vector. That is, the x-axis direction and the Y-axis direction indicate directions parallel to the upper or lower surface of the first redistribution structure 100, and the X-axis direction may be perpendicular to the Y-axis direction. The Z-axis direction may indicate a direction perpendicular to the upper or lower surface of the first redistribution structure 100, in other words, a direction perpendicular to the X-Y plane. In addition, in the drawings below, a first horizontal direction, a second horizontal direction, and the vertical direction may be understood as follows. It may be understood that the first horizontal direction is the X-axis direction referred to as a first horizontal direction X, the second horizontal direction is the Y-axis direction referred to as a second horizontal direction Y, and the vertical direction is the Z-axis direction referred to as a vertical direction Z.

In some implementations, the first redistribution insulating layer 110 may be provided as a plurality of insulating layers mutually stacked in the vertical direction Z. The first redistribution insulating layer 110 may be formed of, for example, a photo imageable dielectric (PID) or photosensitive polyimide (PSPI).

The first redistribution pattern 130 may be formed inside each of the plurality of insulating layers of the first redistribution insulating layer 110, the plurality of insulating layers being mutually stacked in the vertical direction Z. The first redistribution pattern 130 may include, for example, a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof, but is not limited thereto. In some implementations, the first redistribution pattern 130 may be formed by stacking a metal or an alloy of the metal on a seed layer including Cu, Ti, titanium nitride, or titanium tungsten.

The first redistribution pattern 130 may include a first redistribution line pattern 133 and a first redistribution via pattern 131. The first redistribution line pattern 133 may extend in the first horizontal direction X, and the first redistribution via pattern 131 may extend in the vertical direction Z. The first redistribution pattern 130 may have a multi-layer structure including the first redistribution line pattern 133 and the first redistribution via pattern 131 that are alternately stacked. The first redistribution line pattern 133 may have a shape extending in the horizontal direction along at least one of the upper and lower surfaces of each of the plurality of insulating layers of the first redistribution insulating layer 110. The first redistribution via pattern 131 may have a shape extending by penetrating the first redistribution insulating layer 110 in the vertical direction Z. The first redistribution via pattern 131 may electrically connect between first redistribution line patterns 133 at different levels in the vertical direction Z. In some implementations, at least some of first redistribution line patterns 133 may be integrally formed with some of first redistribution via patterns 131. In some implementations, the first redistribution via pattern 131 may have a tapered shape with a horizontal width gradually decreasing as the vertical level of the first redistribution via pattern 131 decreases. However, the shape of the first redistribution via pattern 131 is not limited thereto, and the first redistribution via pattern 131 may have a shape with a horizontal width gradually increasing as the vertical level of the first redistribution via pattern 131 decreases or with a constant horizontal width.

The first redistribution pattern 130 may be electrically connected to the conductive pillar 380 and the first chip 300. The first redistribution pattern 130 may include the first redistribution via pattern 131 and the first redistribution line pattern 133. The first redistribution line pattern 133 may have a shape extending in the first horizontal direction X inside the first redistribution insulating layer 110. In some implementations, the first redistribution line pattern 133 may be provided to each of the plurality of insulating layers of the first redistribution insulating layer 110, stacked in the vertical direction Z. The first redistribution via pattern 131 may extend in the vertical direction Z and penetrate the first redistribution insulating layer 110 in the vertical direction Z. The first redistribution via pattern 131 may electrically connect between first redistribution line patterns 133 respectively formed in different insulating layers of the first redistribution insulating layer 110.

In some implementations, the first redistribution via pattern 131 may have a tapered shape extending with a gradually increasing horizontal width from the bottom to the top. For example, the first redistribution via pattern 131 may have a horizontal width gradually increasing toward the first chip 300. In some implementations, the first redistribution via pattern 131 may have a tapered shape with a horizontal width gradually increasing as the vertical level of the first redistribution via pattern 131 decreases. Alternatively, in some implementations, the first redistribution via pattern 131 may have a shape with the same horizontal width regardless of a level in the vertical direction Z.

In some implementations, the first redistribution structure 100 may be a printed circuit board (PCB). In this case, the first redistribution insulating layer 110 may include at least one material selected from among a phenol resin, an epoxy resin, and polyimide. The first redistribution insulating layer 110 may include at least one material selected from among, for example, frame retardant 4 (FR-4), tetrafunctional epoxy, polyphenylene ether, epoxy/polyphenylene oxide, bismaleimide triazine (BT), Thermount, cyanate ester, polyimide, and liquid crystal polymer. In addition, the first redistribution pattern 130 may include Cu, Ni, stainless steel, or beryllium copper.

The external connection terminal 160 may be beneath the first redistribution structure 100. The external connection terminal 160 may be physically connected to an external device, e.g., a motherboard. The external connection terminal 160 may be physically connected to the first redistribution pattern 130. Through the first redistribution pattern 130, the external connection terminal 160 may transfer an electrical signal received from the first chip 300, the second chip 400, and the third chip 500 to an external device or transfer an electrical signal received from the external device to the first chip 300, the second chip 400, and the third chip 500. The external connection terminal 160 may include a conductive material, e.g., at least one of solder, Sn, silver (Ag), Cu, and Al.

The first chip 300 may be mounted on the upper surface of the first redistribution structure 100. The first chip 300 may be electrically connected to the first redistribution pattern 130. In some implementations, the first chip 300 may be mounted on the first redistribution structure 100 in a flip chip manner. For example, the first chip 300 may be mounted on the first redistribution structure 100 in a flip chip manner through a first bump 350. In some implementations, the first bump 350 and a first underfill material layer 340 surrounding the first bump 350 may be between the first chip 300 and the first redistribution structure 100. The first underfill material layer 340 may fix the first bump 350. The first underfill material layer 340 may include, for example, an epoxy resin formed in a capillary underfill method. However, in some implementations, the molding member 390 may directly fill a gap between the first chip 300 and the first redistribution structure 100 through a molded underfill process. In this case, the first underfill material layer 340 may be omitted.

The first chip 300 is a semiconductor chip and may include a first semiconductor substrate 330 and a device layer 310. The first semiconductor substrate 330 may include silicon (Si), e.g., crystalline Si, polycrystalline Si, or amorphous Si. Alternatively, the first semiconductor substrate 330 may include a semiconductor element, such as germanium (Ge), or a compound semiconductor, such as silicon carbide (SiC), gallium arsenide (GaAs), indium arsenide (InAs), or indium phosphide (InP). The device layer 310 may include a plurality of semiconductor devices and an interlayer insulating layer covering the plurality of semiconductor devices. The plurality of semiconductor devices may include switching devices, e.g., transistors. The first chip 300 may be mounted on the upper surface of the first redistribution structure 100 such that the device layer 310 faces the first redistribution structure 100. In some implementations, a circuit gap of the first chip 300 may be greater than a circuit gap of the second chip 400.

In some implementations, the first chip 300 is a chip at a lower side in an existing three-dimensional (3D) integrated circuit (IC) and may include a processor, a central processing unit (CPU), a graphics processing unit (GPU), a micro processor unit (MPU), and static random access memory (SRAM).

However, the first chip 300 is not limited thereto and may include a memory chip or a logic chip. The memory chip may include, for example, a volatile memory chip, such as dynamic random access memory (DRAM) or SRAM, or a nonvolatile memory chip, such as phase change random access memory (PRAM), magnetoresistive random access memory (MRAM), ferroelectric random access memory (FeRAM), or resistive random access memory (RRAM). The logic chip may include, for example, a microprocessor, such as a CPU, a GPU, or an application processor (AP), an analog device, or a digital signal processor.

A through electrode 335 may be formed to penetrate the first semiconductor substrate 330 in the vertical direction Z. In some implementations, the through electrode 335 may penetrate the first semiconductor substrate 330 from the upper surface to the lower surface of the first semiconductor substrate 330 in the vertical direction Z and further penetrate a portion of the device layer 310 in the vertical direction Z.

The upper surface of the through electrode 335 may be at the same vertical level as the upper surface of the first semiconductor substrate 330. The upper surface of the through electrode 335 may be exposed upward in the vertical direction Z from the first semiconductor substrate 330. The upper surface of the through electrode 335 may be physically connected to a second redistribution pattern 230. Particularly, the upper surface of the through electrode 335 may be physically connected to a second redistribution via pattern 231. The first chip 300 may be electrically connected to the second redistribution structure 200 through the through electrode 335. Particularly, the device layer 310 of the first chip 300 may be electrically connected to the second redistribution pattern 230 through the through electrode 335.

The molding member 390 may be formed on the upper surface of the first redistribution structure 100 so as to surround the first chip 300. In some implementations, the molding member 390 may surround the side surfaces of the first chip 300. By surrounding the side surfaces of the first chip 300 with the molding member 390, the upper surface of the first chip 300 may be exposed upward in the vertical direction Z from the molding member 390. In some implementations, the upper surface of the first chip 300 may be coplanar with the upper surface of the molding member 390. Particularly, the upper surface of the first semiconductor substrate 330 may be coplanar with the upper surface of the molding member 390. In addition, the upper surface of the through electrode 335 may be coplanar with the upper surface of the molding member 390.

The molding member 390 may be formed of a thermosetting resin, such as an epoxy resin, a thermoplastic resin, such as polyimide, or a resin, particularly, an Ajinomoto build-up film (ABF), FR-4, BT, or the like, obtained by adding a reinforcement material, such as inorganic filler, to the thermosetting or thermoplastic resin, but is not limited thereto, and the molding member 390 may be formed of a molding material, such as an epoxy mold compound (EMC), or a photosensitive material, such as photoimageable encapsulant (PIE). In some implementations, a portion of the molding member 390 may include an insulating material, such as a silicon oxide layer, a silicon nitride layer, or a silicon oxynitride layer.

The conductive pillar 380 may be on the upper surface of the first redistribution structure 100 and spaced apart from the first chip 300 in the horizontal direction. In some implementations, a plurality of conductive pillars 380 may be provided. The plurality of conductive pillars 380 may be spaced apart from each other by a certain distance in the horizontal direction. The conductive pillar 380 may have a shape extending in the vertical direction Z and penetrate the molding member 390 in the vertical direction Z.

The conductive pillar 380 may electrically connect the second redistribution structure 200 to the first redistribution structure 100. That is, the conductive pillar 380 may be a vertical connection conductor electrically connecting the first redistribution structure 100 to the second redistribution structure 200. In some implementations, the upper surface of the conductive pillar 380 may be coplanar with the upper surface of the molding member 390.

The second redistribution structure 200 may be on the upper surface of the molding member 390. The second redistribution structure 200 may include upper and lower surfaces that are opposite to each other, and at least one of the upper and lower surfaces of the second redistribution structure 200 may be flat. The second redistribution structure 200 may electrically connect between the conductive pillar 380 and the second chip 400 and between the conductive pillar 380 and the third chip 500. The second redistribution structure 200 may include a second redistribution insulating layer 210 and the second redistribution pattern 230. The second redistribution structure 200 may electrically connect between the conductive pillar 380 and the second chip 400 through the second redistribution pattern 230. A second redistribution insulating layer 210 may be provided as a plurality of layers stacked in the vertical direction Z. The second redistribution pattern 230 may include the second redistribution via pattern 231 and a second redistribution line pattern 233.

The second redistribution insulating layer 210 and the second redistribution pattern 230 are substantially the same as or similar to the first redistribution insulating layer 110 and the first redistribution pattern 130 described above, and thus, a repeated description thereof is omitted herein.

The second chip 400 may be mounted on the upper surface of the second redistribution structure 200. The second chip 400 may be mounted on the upper surface of the second redistribution structure 200 in a flip chip manner through a second bump 450. A second underfill material layer 440 may be between the second chip 400 and the second redistribution structure 200 while surrounding the second bump 450.

The second chip 400 corresponds to an upper chip in an existing 3D IC chip, and a circuit gap of the second chip 400 may be less than a circuit gap of the first chip 300. However, the second chip 400 is not limited thereto and may include a memory chip or a logic chip.

In some implementations, the vertical level of the upper surface of the second chip 400 may be the same as the vertical level of the upper surface of the third chip 500, similar to the semiconductor package 10 shown in FIG. 1A. However, the upper surface of the second chip 400 may be at a lower vertical level than the upper surface of the third chip 500, similar to the semiconductor package 11 shown in FIG. 1B. A thickness D1 of the second chip 400 in the vertical direction Z may be within a range of about 50 μm to about 700 μm. Depending on the thickness D1 of the second chip 400 in the vertical direction Z, the upper surface of the second chip 400 may be at a lower vertical level than or the same vertical level as the upper surface of the third chip 500. In addition, the thickness of the third chip 500 is not limited to FIGS. 1A and 1B, and depending on the thickness of the third chip 500 in the vertical direction Z, the upper surface of the second chip 400 may be at a lower vertical level than or the same vertical level as the upper surface of the third chip 500.

In some implementations, the second chip 400 may receive a power signal from an external device through the second redistribution pattern 230 connected to the conductive pillar 380 or through the second redistribution pattern 230 connected to the through electrode 335 of the first chip 300. That is, the second chip 400 may receive a power signal transferred from an external device to the semiconductor packages 10 and 11, through the first redistribution pattern 130, the first bump 350, the through electrode 335, and the second redistribution pattern 230 or through the first redistribution pattern 130, the conductive pillar 380, and the second redistribution pattern 230. In addition, the second chip 400 may receive a signaling signal through the through electrode 335 of the first chip 300. Particularly, the second chip 400 may exchange a signaling signal with the first chip 300 through the through electrode 335 of the first chip 300 and the second redistribution pattern 230.

The third chip 500 may be on the upper surface of the second redistribution structure 200 and spaced apart from the second chip 400 in the first horizontal direction X. In some implementations, the third chip 500 is a memory chip and may include a DRAM chip. The third chip 500 may be mounted on the upper surface of the second redistribution structure 200 in a flip chip manner through a third bump 550. In some implementations, an underfill material layer surrounding the third bump 550 may be between the third chip 500 and the second redistribution structure 200. In some implementations, the third bump 550 may have a greater volume than the second bump 450.

In some implementations, the third chip 500 may receive a power signal from an external device through the second redistribution pattern 230 connected to the conductive pillar 380. The second chip 400 may receive a power signal transferred from an external device to the semiconductor packages 10 and 11, through the first redistribution pattern 130, the first bump 350, and the second redistribution pattern 230. In addition, the third chip 500 may receive a signaling signal through the through electrode 335 of the first chip 300. Particularly, the third chip 500 may exchange a signaling signal with the first chip 300 through the through electrode 335 of the first chip 300 and the second redistribution pattern 230.

In the semiconductor packages 10 and 11 with the first chip 300 and the second chip 400 stacked in the vertical direction Z in an existing 3D IC structure, by disposing the second chip 400 generating relatively much heat on the upper surface of the second redistribution structure 200 and disposing the first chip 300 generating relatively little heat inside the molding member 390, the heat generated from the first chip 300 may be discharged to the outside through the second redistribution structure 200, and the heat generated from the second chip 400 may be discharged directly to the outside. Eventually, the semiconductor packages 10 and 11 may easily discharge heat generated therein to the outside.

In addition, by separately mounting the first chip 300 and the second chip 400 in the semiconductor packages 10 and 11 without stacking the first chip 300 and the second chip 400 in a 3D structure, costs consumed according to 3D assembly may be saved. In addition, by forming the through electrode 335 in the first chip 300 surrounded by the molding member 390, exposing the through electrode 335 upward in the vertical direction Z from the molding member 390, and connecting the through electrode 335 to the second redistribution pattern 230, a role of the first chip 300 and the second chip 400 in an existing 3D structure may be performed as the role is.

In some implementations, each of the second chip 400 and the third chip 500 may overlap the first chip 300 in the vertical direction Z. That is, a portion of the first chip 300 may overlap the second chip 400 in the vertical direction Z, and a portion of the first chip 300 may overlap the third chip 500 in the vertical direction Z. According to the overlapping of the first chip 300 with each of the second chip 400 and the third chip 500 in the vertical direction Z, a signal path between the first chip 300 and the second chip 400 or between the first chip 300 and the third chip 500 may be shortened.

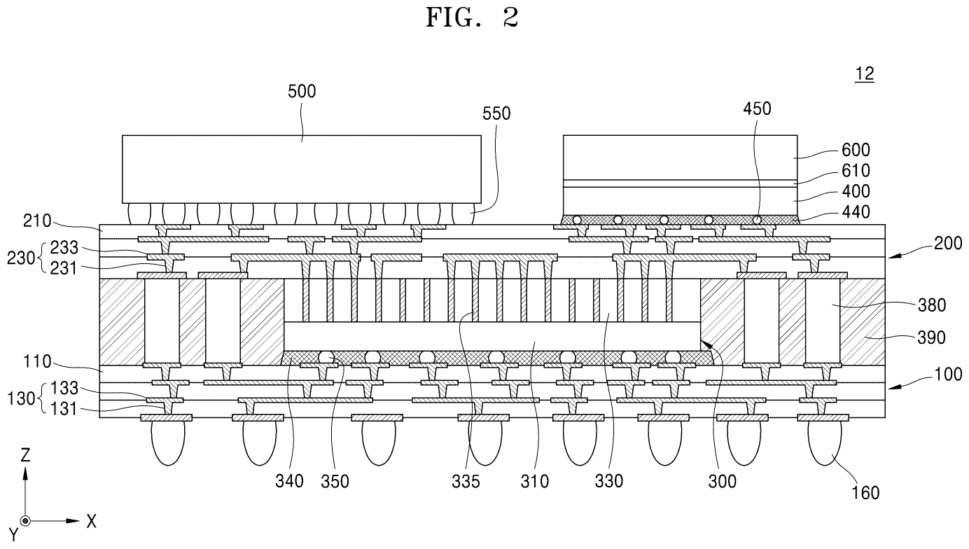

FIG. 2 is a cross-sectional view illustrating an example of a semiconductor package 12. Hereinafter, a description made for the semiconductor packages 10 and 11 with reference to FIGS. 1A and 1B is not repeated to describe the semiconductor package 12 of FIG. 2, and differences therebetween are mainly described.

Referring to FIG. 2, the semiconductor package 12 may include the first redistribution structure 100, the first chip 300, the molding member 390, the conductive pillar 380, the second redistribution structure 200, the second chip 400, an adhesive layer 610, a dummy chip 600, and the third chip 500.

The first redistribution structure 100 may be beneath the first chip 300 and include the first redistribution insulating layer 110 and the first redistribution pattern 130. The first redistribution insulating layer 110 may be provided as a plurality of insulating layers stacked in one direction, and the first redistribution pattern 130 may be formed in the plurality of insulating layers that are stacked. The first redistribution pattern 130 may include the first redistribution line pattern 133 and the first redistribution via pattern 131. The first chip 300 may be mounted on the upper surface of the first redistribution structure 100. The first chip 300 may include the first semiconductor substrate 330 and the device layer 310. The through electrode 335 may be formed to penetrate the first semiconductor substrate 330 in the vertical direction Z. The molding member 390 may be formed on the upper surface of the first redistribution structure 100 so as to surround the first chip 300. The conductive pillar 380 may penetrate the molding member 390 in the vertical direction Z. The second redistribution structure 200 may be on the upper surface of the molding member 390 and include the second redistribution insulating layer 210 and the second redistribution pattern 230. The second redistribution pattern 230 may include the second redistribution via pattern 231 and the second redistribution line pattern 233. The second chip 400 may be mounted on the upper surface of the second redistribution structure 200. In some implementations, the upper surface of the second chip 400 may be at a lower vertical level than the upper surface of the third chip 500.

The dummy chip 600 may be on the second chip 400. The dummy chip 600 may include Si. The adhesive layer 610 may be between the dummy chip 600 and the second chip 400. In some implementations, the adhesive layer 610 may be configured such that the dummy chip 600 is attached to the second chip 400. The adhesive layer 610 may include a film having an adhesive property. For example, the adhesive layer 610 may be a double-sided adhesive film. In some implementations, the adhesive layer 610 may include a tape-shaped material layer, a liquid coating hardening material layer, or a combination thereof. In addition, the adhesive layer 610 may include a thermal setting structure, thermal plastic, an ultraviolet (UV) cure material, or a combination thereof. The adhesive layer 610 may be referred to as a die attach film (DAF) or a non-conductive film (NCF). The upper surface of the dummy chip 600 may be at substantially the same vertical level as the upper surface of the third chip 500.

In the semiconductor package 12, when the upper surface of the second chip 400 has a lower vertical level than the upper surface of the third chip 500 and chips mounted on the upper surface of the second redistribution structure 200 are required to have a uniform thickness in the vertical direction Z, the dummy chip 600 may be on the second chip 400 such that the upper surface of the third chip 500 and the upper surface of the dummy chip 600 have substantially the same vertical level, thereby making the thicknesses of chips mounted on the upper surface of the second redistribution structure 200 be the same in the vertical direction Z. In addition, heat generated from the second chip 400 may be further easily discharged to the outside through the dummy chip 600 including Si.

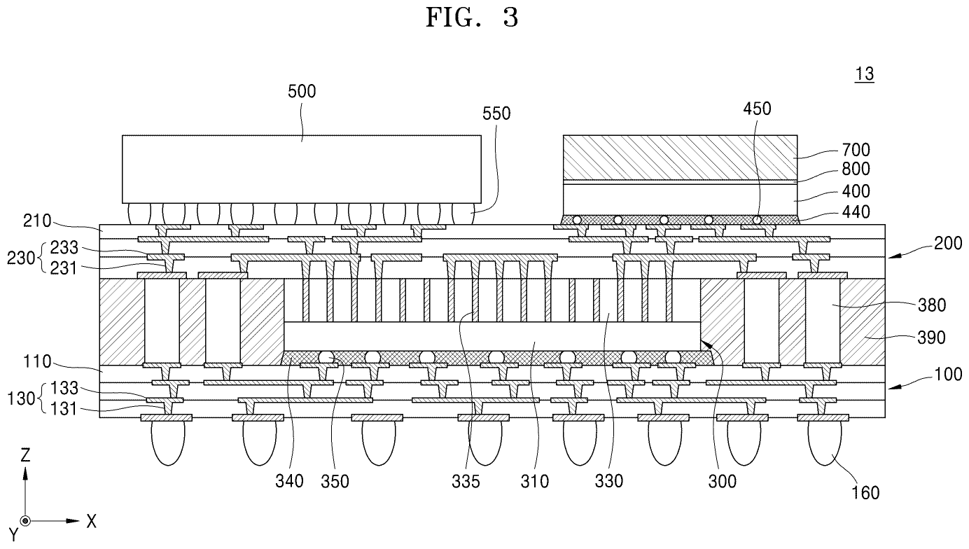

FIG. 3 is a cross-sectional view illustrating another example of a semiconductor package 13. Hereinafter, a description made for the semiconductor package 12 with reference to FIG. 2 is not repeated to describe the semiconductor package 13 of FIG. 3, and differences therebetween are mainly described.

Referring to FIG. 3, the semiconductor package 13 may include the first redistribution structure 100, the first chip 300, the molding member 390, the conductive pillar 380, the second redistribution structure 200, the second chip 400, a thermal interfacial material (TIM) layer 800, a heat-dissipating member 700, and the third chip 500.

The first redistribution structure 100 may be beneath the first chip 300 and include the first redistribution insulating layer 110 and the first redistribution pattern 130. The first redistribution insulating layer 110 may be provided as a plurality of insulating layers stacked in one direction, and the first redistribution pattern 130 may be formed in the plurality of insulating layers that are stacked. The first redistribution pattern 130 may include the first redistribution line pattern 133 and the first redistribution via pattern 131. The first chip 300 may be mounted on the upper surface of the first redistribution structure 100. The first chip 300 may include the first semiconductor substrate 330 and the device layer 310. The through electrode 335 may be formed to penetrate the first semiconductor substrate 330 in the vertical direction Z. The molding member 390 may be formed on the upper surface of the first redistribution structure 100 so as to surround the first chip 300. The conductive pillar 380 may penetrate the molding member 390 in the vertical direction Z. The second redistribution structure 200 may be on the upper surface of the molding member 390 and include the second redistribution insulating layer 210 and the second redistribution pattern 230. The second redistribution pattern 230 may include the second redistribution via pattern 231 and the second redistribution line pattern 233. The second chip 400 may be mounted on the upper surface of the second redistribution structure 200. In some implementations, the upper surface of the second chip 400 may be at a lower vertical level than the upper surface of the third chip 500.

The heat-dissipating member 700 may be on the second chip 400. The TIM layer 800 may be between the heat-dissipating member 700 and the second chip 400. The heat-dissipating member 700 may be fixed to the upper surface of the second chip 400 through the TIM layer 800. In some implementations, the upper surface of the heat-dissipating member 700 may be at substantially the same vertical level as the upper surface of the third chip 500. In some implementations, the TIM layer 800 may be made of an insulating material or a material including an insulating material and capable of maintaining an electrical insulating property. The TIM layer 800 may include, for example, an insulating base layer, such as an epoxy resin, and a heat-dissipating filler contained in the insulating base layer. The TIM layer 800 may include, for example, mineral oil, grease, gap filler putty, phase change gel, phase change material pads, or particle filled epoxy.

In the semiconductor package 13, the heat-dissipating member 700 may be provided on the upper surface of the second chip 400 through the TIM layer 800. Because the heat-dissipating member 700 includes a material having a high thermal conductivity, heat generated from the second chip 400 may be further easily discharged to the outside through the heat-dissipating member 700.

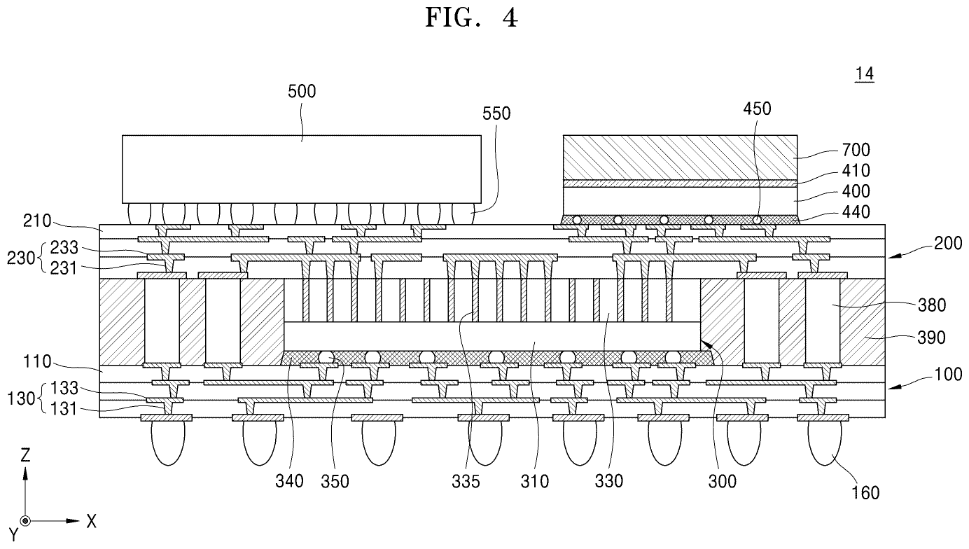

FIG. 4 is a cross-sectional view illustrating another example of a semiconductor package 14. Hereinafter, a description made for the semiconductor package 13 with reference to FIG. 3 is not repeated to describe the semiconductor package 14 of FIG. 4, and differences therebetween are mainly described.

Referring to FIG. 4, the semiconductor package 14 may include the first redistribution structure 100, the first chip 300, the molding member 390, the conductive pillar 380, the second redistribution structure 200, the second chip 400, a metal layer 410, the heat-dissipating member 700, and the third chip 500.

The first redistribution structure 100 may be beneath the first chip 300 and include the first redistribution insulating layer 110 and the first redistribution pattern 130. The first redistribution insulating layer 110 may be provided as a plurality of insulating layers stacked in one direction, and the first redistribution pattern 130 may be formed in the plurality of insulating layers that are stacked. The first redistribution pattern 130 may include the first redistribution line pattern 133 and the first redistribution via pattern 131. The first chip 300 may be mounted on the upper surface of the first redistribution structure 100. The first chip 300 may include the first semiconductor substrate 330 and the device layer 310. The through electrode 335 may be formed to penetrate the first semiconductor substrate 330 in the vertical direction Z. The molding member 390 may be formed on the upper surface of the first redistribution structure 100 so as to surround the first chip 300. The conductive pillar 380 may penetrate the molding member 390 in the vertical direction Z. The second redistribution structure 200 may be on the upper surface of the molding member 390 and include the second redistribution insulating layer 210 and the second redistribution pattern 230. The second redistribution pattern 230 may include the second redistribution via pattern 231 and the second redistribution line pattern 233. The second chip 400 may be mounted on the upper surface of the second redistribution structure 200. In some implementations, the upper surface of the second chip 400 may be at a lower vertical level than the upper surface of the third chip 500.

The metal layer 410 may be formed on the upper surface of the second chip 400. The metal layer 410 may be formed by sputtering or plating a metal on the upper surface of the second chip 400. In some implementations, the metal layer 410 may include Cu. The heat-dissipating member 700 may be on the metal layer 410. In some implementations, the heat-dissipating member 700 may include the same metal material as the metal layer 410. For example, the heat-dissipating member 700 may include Cu. The heat-dissipating member 700 may be fixed to the metal layer 410 by direct bonding. Direct bonding may be diffusion bonding by which two interfaces including the same material are arranged to face each other and then be in contact with each other, and heat is applied to the two interfaces such that metal atoms or dielectric materials in contact with each other are integrated through diffusion. In some implementations, the heat-dissipating member 700 may be formed by metal-metal bonding that is one example of direct bonding. By forming the heat-dissipating member 700 by metal-metal bonding, both the metal layer 410 and the heat-dissipating member 700 on the second chip 400 include a metal having a high thermal conductivity, and accordingly, heat generated from the second chip 400 may be further easily discharged to the outside.

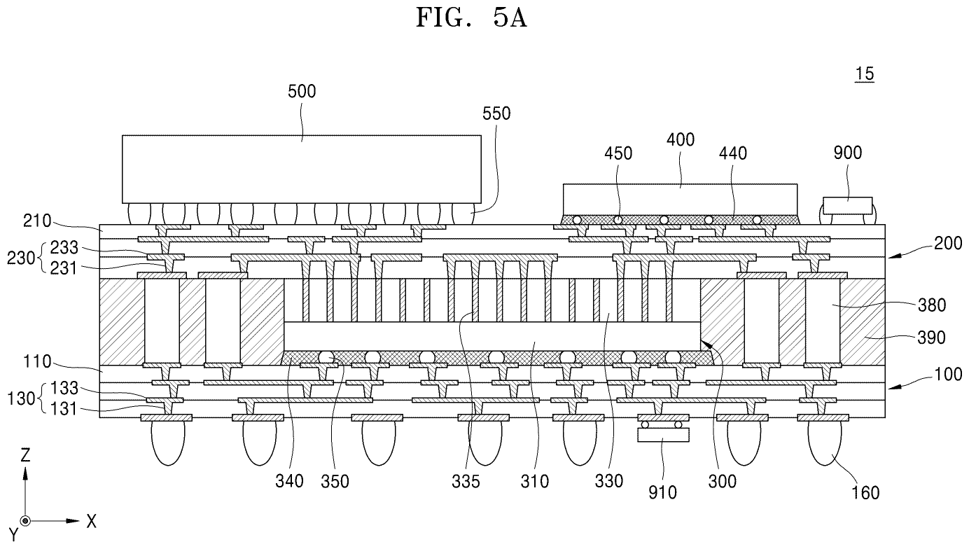

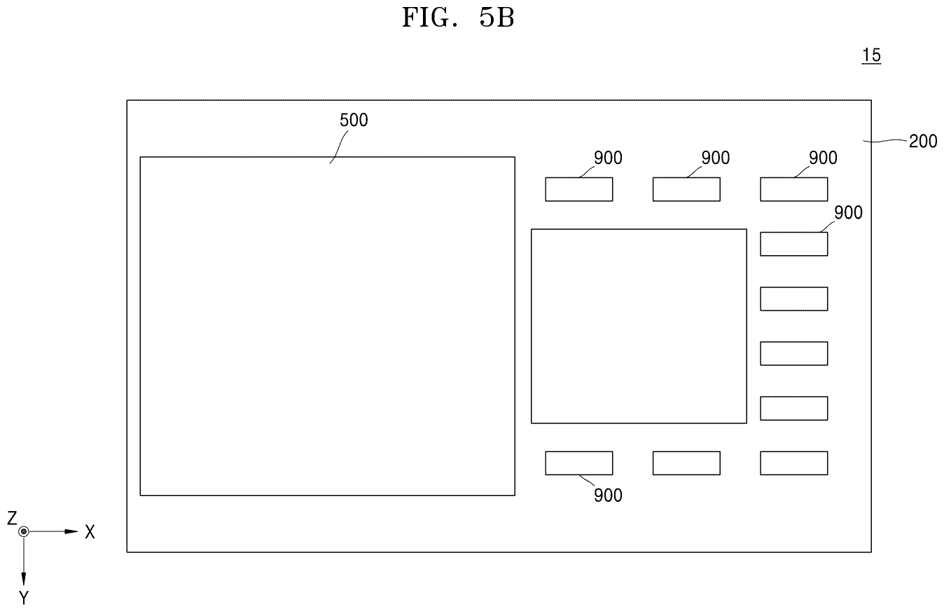

FIG. 5A is a cross-sectional view illustrating another example of a semiconductor package 15. FIG. 5B is a top view illustrating an example of the semiconductor package 15.

Hereinafter, a description made for the semiconductor package 11 with reference to FIG. 1B is not repeated to describe the semiconductor package 15 of FIGS. 5A and 5B, and differences therebetween are mainly described.

Referring to FIGS. 5A and 5B, the semiconductor package 15 may include the first redistribution structure 100, the first chip 300, the molding member 390, the conductive pillar 380, the second redistribution structure 200, the second chip 400, a first passive device 910, a second passive device 900, and the third chip 500.

The first redistribution structure 100 may be beneath the first chip 300 and include the first redistribution insulating layer 110 and the first redistribution pattern 130. The first redistribution insulating layer 110 may be provided as a plurality of insulating layers stacked in one direction, and the first redistribution pattern 130 may be formed in the plurality of insulating layers that are stacked. The first redistribution pattern 130 may include the first redistribution line pattern 133 and the first redistribution via pattern 131. The first chip 300 may be mounted on the upper surface of the first redistribution structure 100. The first chip 300 may include the first semiconductor substrate 330 and the device layer 310. The through electrode 335 may be formed to penetrate the first semiconductor substrate 330 in the vertical direction Z. The molding member 390 may be formed on the upper surface of the first redistribution structure 100 so as to surround the first chip 300. The conductive pillar 380 may penetrate the molding member 390 in the vertical direction Z. The second redistribution structure 200 may be on the upper surface of the molding member 390 and include the second redistribution insulating layer 210 and the second redistribution pattern 230. The second redistribution pattern 230 may include the second redistribution via pattern 231 and the second redistribution line pattern 233. The second chip 400 may be mounted on the upper surface of the second redistribution structure 200. In some implementations, the upper surface of the second chip 400 may be at a lower vertical level than the upper surface of the third chip 500. However, the implementations are not limited thereto, and the upper surface of the second chip 400 may be at the same vertical level as the upper surface of the third chip 500.

The first passive device 910 may be provided beneath the first redistribution structure 100, and the second passive device 900 may be provided on the upper surface of the second redistribution structure 200 and in the vicinity of the second chip 400. The first passive device 910 and the second passive device 900 may include a capacitor or a resistor. For example, the first passive device 910 and the second passive device 900 may include a capacitor, such as an integrated stack capacitor (ISC), a multi-layer ceramic capacitor (MLCC), or a low inductance chip capacitor (LICC), an inductor, a bead, or the like.

In the semiconductor package 15, by providing the first passive device 910 beneath the first redistribution structure 100 so as to be in the vicinity of the first chip 300 and providing the second passive device 900 on the upper surface of the second redistribution structure 200 and in the vicinity of the second chip 400, an electrical signal path between the first chip 300 and the first passive device 910 and between the second chip 400 and the second passive device 900 may be shortened.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been shown and described with reference to implementations thereof, it will be understood that various changes in form and details may be made therein without departing from the spirit and scope of the following claims.

What is claimed is:

1. A semiconductor package comprising:
a first redistribution structure comprising a first redistribution insulating layer and a first redistribution pattern, the first redistribution pattern being in the first redistribution insulating layer;
a first chip on the first redistribution structure;
a molding member on the first redistribution structure, the molding member surrounding the first chip;
a conductive pillar extending through the molding member in a vertical direction;
a second redistribution structure on the first chip and the molding member, the second redistribution structure comprising a second redistribution insulating layer and a second redistribution pattern, the second redistribution pattern being in the second redistribution insulating layer;
a second chip on the second redistribution structure; and
a third chip on the second redistribution structure, the third chip being spaced apart from the second chip in a horizontal direction,
wherein the first chip comprises a first semiconductor substrate and a through electrode, the through electrode extends through the first semiconductor substrate in the vertical direction, and the through electrode is in contact with the second redistribution pattern.

2. The semiconductor package of claim 1, wherein an upper surface of the first chip is coplanar with an upper surface of the molding member.

3. The semiconductor package of claim 1, wherein the second redistribution pattern comprises a second redistribution line pattern and a second redistribution via pattern, and the second redistribution via pattern is connected with the through electrode.

4. The semiconductor package of claim 1, wherein an upper surface of the second chip is lower than an upper surface of the third chip in the vertical direction.

5. The semiconductor package of claim 1, comprising:
a dummy chip on the second chip; and
an adhesive layer between the second chip and the dummy chip.

6. The semiconductor package of claim 1, wherein the first chip is connected with the first redistribution pattern through a first bump, the first bump being between the first chip and the first redistribution structure.

7. The semiconductor package of claim 1, comprising:
a first passive device beneath the first redistribution structure; and
a second passive device on an upper surface of the second redistribution structure and in the vicinity of the second chip.

8. The semiconductor package of claim 1, comprising a heat-dissipating member on the second chip.

9. The semiconductor package of claim 8, comprising a thermal interfacial material (TIM) layer between the second chip and the heat-dissipating member.

10. The semiconductor package of claim 8, comprising a metal layer on an upper surface of the second chip.

11. The semiconductor package of claim 1, wherein a thickness of the second chip in the vertical direction is within a range of 50 μm to 700 μm.

12. A semiconductor package comprising:
a first redistribution structure comprising a first redistribution insulating layer and a first redistribution pattern, the first redistribution pattern being in the first redistribution insulating layer;
a first chip on the first redistribution structure;
a molding member on the first redistribution structure, the molding member surrounding the first chip;
a conductive pillar extending through the molding member in a vertical direction;
a second redistribution structure on the first chip and the molding member, the second redistribution structure comprising a second redistribution insulating layer and a second redistribution pattern, the second redistribution pattern being in the second redistribution insulating layer;
a second chip on the second redistribution structure;
a third chip on the second redistribution structure, the third chip being spaced apart from the second chip in a horizontal direction; and
a heat-dissipating member on the second chip,
wherein the first chip comprises a first semiconductor substrate and a through electrode, the through electrode extends through the first semiconductor substrate in the vertical direction, the through electrode is in contact with the second redistribution pattern, an upper surface of the second chip is lower than an upper surface of the third chip in the vertical direction, and a circuit gap of the second chip is narrower than a circuit gap of the first chip.

13. The semiconductor package of claim 12, wherein the second chip is configured to receive a power signal through at least one of the through electrode or the conductive pillar, and the third chip is configured to receive the power signal through the conductive pillar.

14. The semiconductor package of claim 12, wherein the first chip overlaps the second chip and the third chip in the vertical direction.

15. The semiconductor package of claim 12, comprising:
a first passive device beneath the first redistribution structure; and
a second passive device on an upper surface of the second redistribution structure and in the vicinity of the second chip.

16. The semiconductor package of claim 12, comprising a thermal interfacial material (TIM) layer between the second chip and the heat-dissipating member.

17. The semiconductor package of claim 12, comprising a metal layer on an upper surface of the second chip, wherein each of the metal layer and the heat-dissipating member includes copper.

18. A semiconductor package comprising:
a first redistribution structure comprising a first redistribution insulating layer and a first redistribution pattern, the first redistribution pattern being in the first redistribution insulating layer;
a first passive device beneath the first redistribution structure;
a first chip on the first redistribution structure;
a molding member on the first redistribution structure, the molding member surrounding the first chip;
a conductive pillar extending through the molding member in a vertical direction;
a second redistribution structure on the first chip and the molding member, the second redistribution structure comprising a second redistribution insulating layer and a second redistribution pattern, the second redistribution pattern being in the second redistribution insulating layer;
a second chip on the second redistribution structure;
a plurality of second passive devices on the second redistribution structure, the plurality of second passive devices surrounding a plurality of side surfaces of the second chip;
a third chip on the second redistribution structure, the third chip being spaced apart from the second chip in a horizontal direction;
a metal layer on an upper surface of the second chip; and
a heat-dissipating member coupled to an upper surface of the metal layer,
wherein the first chip comprises a first semiconductor substrate and a through electrode, the through electrode extends through the first semiconductor substrate in the vertical direction, the through electrode is in contact with the second redistribution pattern, an upper surface of the second chip is lower than an upper surface of the third chip in the vertical direction, a circuit gap of the second chip is narrower than a circuit gap of the first chip, and each of the metal layer and the heat-dissipating member includes copper.

19. The semiconductor package of claim 18, wherein a thickness of the second chip in the vertical direction is within a range of 50 μm to 700 μm.

20. The semiconductor package of claim 18, wherein the second redistribution pattern comprises a second redistribution line pattern and a second redistribution via pattern, and the second redistribution via pattern is connected with the through electrode.
